(19) United States
(12) Patent Application Publication
(10) Pub. No.: US 2006/0238980 A1
(43) Pub. Date: Oct. 26, 2006

(54) Increased cooling electronics case

(76) Inventors: Rabindra Kumar Bhattacharyya, Export, PA (US); Joseph Michael Fridy, Pittsburgh, PA (US); Domenic A. Ghiardi, Avonmore, PA (US); Glenn Jarvis, Allison Park, PA (US); John Thomas Siemon JR., Cheswick, PA (US); Peter A. Vranka, Apollo, PA (US)

Correspondence Address: INTELLECTUAL PROPERTY, ALCOA TECHNICAL CENTER, BUILDING C, 100 TECHNICAL DRIVE, ALCOA CENTER, PA, 15069-0001, US

(21) Appl. No.: 11/111,333

(22) Filed: Apr. 21, 2005

(51) Int. Cl. H05K 7/20

(52) U.S. Cl. 361/700

(57) ABSTRACT

The present invention provides an electronics case including a housing having at least one sidewall having an air passage, wherein the air passage includes an intake and an exhaust; a heat producing structure contained by the housing; and at least one heat pipe in conductive communication with the heat producing structure and the sidewalls having the air passage. The air passage within the sidewall produces a chimney effect that vents heated air from the housing. The chimney effect may be produced by a sidewall having a fluted sidewall.

### FIELD OF THE INVENTION

The present invention relates to controlling temperature in heat producing electronic devices. More specifically, the present invention provides an electronics enclosure that regulates the temperature of internal heat producing electronics by using a combination of heat pipes and air passages.

### BACKGROUND OF THE INVENTION

Prior electronic enclosure designs or enclosures for heat producing computer devices suffer from the disadvantages of excessive noise, fluctuating internal temperature, and a lack of robustness in the cooling design of the enclosure. Furthermore, prior electronics enclosures do not provide warning signals that indicate to the user that the cooling of the electrical devices contained within the enclosure is inadequate. Furthermore, prior electronics enclosures do not automatically power down the electronic devices contained within the enclosure in response to adverse heating.

FIG. 1 provides an example of a prior computer enclosure, in which heat producing electronic devices are mounted to mounting plates S1 and S2. Cooling of the heat producing devices mounted on S1 or S2 primarily relies on forced air cooling or a combination of forced air cooling and heat sinks.

Heat is produced within the enclosure by the electronic devices contained therein. Airflow produced by forced air cooling distributes the heat generated at the heat sources into the air within the enclosure by means of convection. Forced air cooling may include any number of mechanical fans. The heated air escapes the enclosure through at least one vent, simultaneously allowing cool air from the exterior environment to enter the enclosure. It is noted that the heat produced by the electronic devices increases the temperature of the enclosure itself. The enclosure transfers the heat produced by the internal electronic devices to the exterior environment.

The rate at which the enclosure transfers heat to the air within the surrounding environment is determined by natural convection. Heat transfer by convection into a confined air space is quite inefficient, having a very slow rate of heat transfer to the exterior environment. Although a computer enclosure that is equipped with vents is not a completely confined environment, the movement of heated air through the vents is only by natural convection initiated by the difference in temperature of air within the enclosure and the temperature of the enclosure itself. Therefore, since the rate of heat transfer to the air within the enclosure and the rate of heat transfer to the enclosure itself are typically slow the vents by themselves do not supply an adequate amount of cooling to the heat producing devices contained within the enclosure.

U.S. Pat. No. 5,884,693 to Austin, et al. represents one prior cooling system for cooling an enclosure containing electronic components and devices. The Austin et al. reference provides an enclosure equipped with heat pipes, wherein the heat pipes increase heat transfer to the enclosure. However, heat transfer from the heat producing source to the enclosure is still disadvantageously controlled by natural convection. Furthermore, since heat transfer from the enclosure to the room is also by natural convection, the rate of heat transfer from the enclosure to the exterior environment is also slow.

U.S. Pat. No. 5,973,920 to Altic, et al. (“Altic, et al.”) provides another example of an enclosure for electronic devices in which a heat frame incorporates a heat sink, a connector and a mounting frame adapted for mounting multiple circuit boards into one integral component. Heat removed by the heat sink is transferred over the entire heat frame with the aid of heat pipes. The design further incorporates fins to dissipate heat through the housing of the computer. Disadvantageously, heat transfer is still controlled by natural convection.

In another prior design, a computer case is provided in which a series of copper heat pipes transfer heat from the heat source contained within the enclosure to the enclosure itself. This is a direct transfer of heat from the heat producing device to the walls of the enclosure. Nevertheless, the enclosure still relies on natural convection to transfer the heat from the enclosure to the air of the surrounding environment.

It is noted that heat transfer via natural convention may be advanced by forced air cooling through the use of motorized fans. The disadvantages of utilizing forced air cooling is the increased likeliness of mechanical failure inherent in motorized fan designs and the excessive noise that is produced by the fans operation.

With increasing computer chip density greater requirements have been placed on device cooling. Therefore, it is desirable that a system of increased cooling be provided to ensure that the computer chips of the next generation do not operate at a sub-optimum level. Further, the noise that is produced by fans and the lack of reliability associated with the moving fan parts provide additional reasons why a new cooling design is needed.

### SUMMARY OF THE INVENTION

The present invention provides an electronics device enclosure having increased cooling capacity to the electronic devices contained therein. The present invention also provides an electronics device enclosure having increased cooling without the use of mechanical fans. The present invention further provides an electronics device enclosure that increases cooling to the electrical devices contained therein with a combination of heat pipes and air passages, wherein the air passages transfer heat from the enclosure to the outside environment by a chimney effect.

The present invention provides the above and more by an electronics device enclosure comprising:
a housing comprising at least one sidewall having an air passage, wherein said air passage includes an intake and an exhaust;
a heat producing structure contained by said housing; and
at least one heat pipe in conductive communication with said heat producing structure and said at least one of said sidewalls having said air passage.

The heat producing structure contained within the electronics case may be a power supply, a motherboard, drive system or any electrical device utilized in computers and personal electronics.

The intake may be a first vent positioned on a lower outside portion of a sidewall containing an air passage and the exhaust may comprise a second vent positioned on an upper outside portion of the sidewall containing the air passage. The sidewalls may further comprise at least one interior vent positioned on the lower and/or upper inside portion of the sidewall of the air passage. The vents may be positioned in any manner that removes the air that has been heated by the heat producing elements from the interior of the electronics case and draws cooler air from the exterior atmosphere.

The heat pipes that are in conductive communication with the heat producing structures and the housing of the electronics case may be aluminum or copper. The term “conductive communication” denotes that the heat pipes transfer heat from the heat producing structure to the sidewalls of the electronic case housing, which include the air passages. The flow of air through the air passage transports the heat transferred by the heat pipe to the sidewall of the electronics case to the exterior atmosphere. The rate of air flow though the sidewall of the electronics case may be dependant on the sidewalls cross section.

In another embodiment of the present invention the electronics case comprises:
a housing comprising at least one fluted sidewall;
a heat producing structure contained by said housing; and
at least one heat pipe in conductive communication with said heat producing structure and said at least one fluted sidewall.

The fluted sidewall has a cross-section that produces a chimney effect, which vents heated air from the housing and draws cool air from the exterior atmosphere into the housing. The term “chimney effect” denotes the movement of heated air out of the enclosure and cooler air into the enclosure resulting from a difference in pressure between the air/gasses inside the enclosure and the exterior environment.

### BRIEF DESCRIPTION OF THE DRAWINGS

FIG. 1. (cross sectional side view) illustrates a prior art computer enclosure.

FIG. 2. (three dimensional view) illustrates one embodiment of the inventive electronics device enclosure.

FIG. 3. (three dimensional view) depicts a heat pipe system utilized in the inventive electronics device enclosure.

FIG. 4. (cross sectional view) represents the cross section of a heat pipe as depicted in FIG. 3.

FIG. 5. (three dimensional view) illustrates another embodiment of the inventive electronics device enclosure in which the sidewall of the housing has a fluted cross section with an inside panel and an outside panel, wherein the outside panel has an intake vent and an exhaust vent.

FIG. 6 (cross sectional view) illustrates the sidewall of the housing of the electronic device enclosure depicted in FIG. 5.

FIG. 7 (three dimensional view) illustrates another embodiment of the inventive electronics device enclosure wherein the sidewall of the electronic device enclosure housing is fluted to provide a chimney effect.

FIG. 8 (cross sectional view) illustrates a cross section of the sidewall of the embodiment of the inventive device electronics device enclosure depicted in FIG. 7.

FIG. 9 (three dimensional view) illustrates one embodiment of the inventive electronics device enclosure, in which a low velocity fan provides increased cooling.

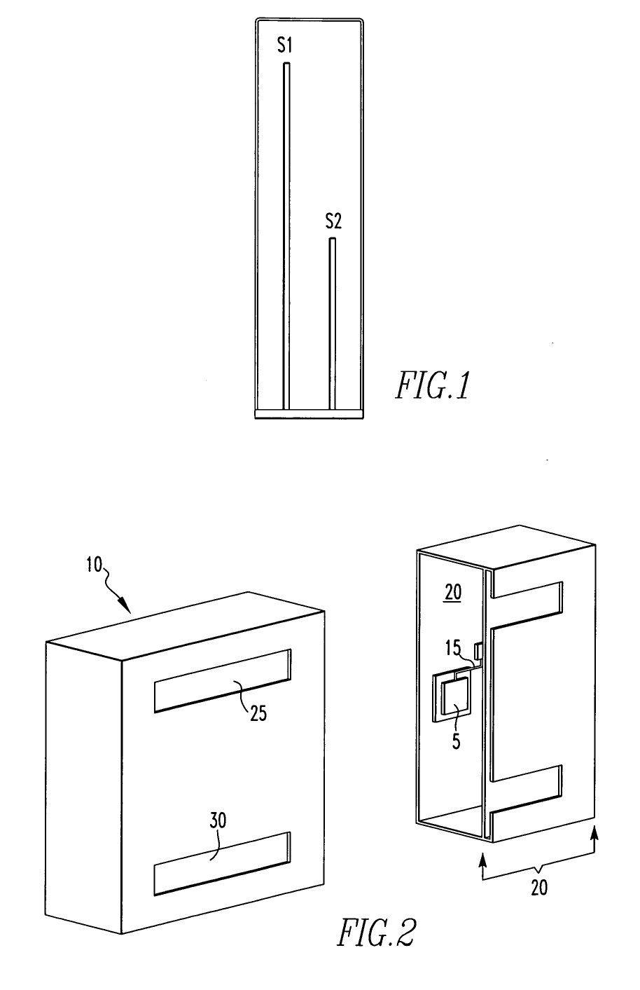

### DETAILED DESCRIPTION OF PREFERRED EMBODIMENTS

The present invention provides an electronics device enclosure having increased cooling to vent heated air from the interior of the electronics device enclosure without the use of mechanical means. More specifically, the inventive electronics device enclosure transfers heat from the heat producing electrical devices contained therein using at least one heat pipe in conductive communication to the housing of the electronics device enclosure.

The heat that is transferred from the heat producing electronics to the housing of the electronics device enclosure is then transferred to the exterior atmosphere by at least one sidewall having an air passage that displays a chimney effect. The chimney effect promotes venting of heated air while simultaneously drawing cooled air into the air passage. The present invention is now discussed in more detail referring to the drawings that accompany the present application. It is noted that in the accompanied drawings like and/or corresponding elements are referred to by like reference numbers.

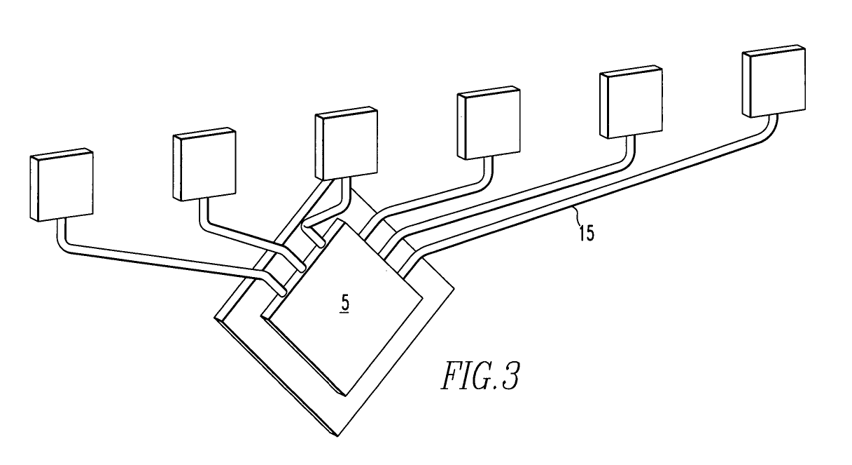

Referring to FIG. 2, an electronics device enclosure is provided comprising a housing 10 that contains at least one heat producing electrical device 5, wherein the heat producing electrical devices 5 are in conductive communication to the housing 10 of the enclosure through at least one heat pipe 15. The heat pipe 15 transfers heat produced by the heat producing device 5 to the sidewall 20 of the electronic device enclosure. The sidewall 20 includes at least one air passage having at least one exhaust vent 25 positioned on the exterior surface of the sidewall 20 and at least one air intake 30 positioned on the lower exterior surface of the sidewall 20. It is noted that although the embodiment depicted in FIG. 2. illustrates only heat pipe 15 and only one sidewall 20 having an air passage, the present invention is equally applicable to a plurality of heat pipes 15 and is equally applicable to enclosures having any number of sidewalls 20 including air passages. The housing 10 may be constructed of aluminum, copper, or steel sheets.

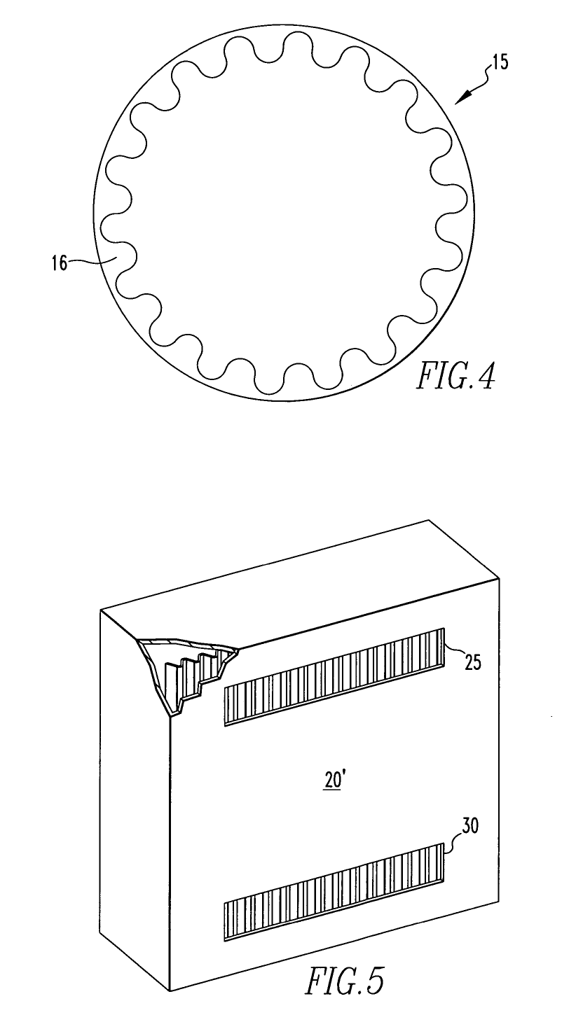

FIG. 3 illustrates one example of a heat pipe system. Each heat pipe 15 comprises a cylinder having an external wall and an internal wall. Each heat pipe 15 is capped at each end and is under a vacuum. One example of the cross section of a heat pipe 15 is depicted in FIG. 4, in which the interior wall of the heat pipe 15 has a plurality of ridges 16. The production of each, heat pipe 15 begins by providing a cylinder filled with a liquid that is selected for its' boiling temperature. Once the heat pipe 15 is filled with the selected liquid it is capped and placed in a vacuum. Although the majority of the liquid is removed during the application of the vacuum, a lesser amount of the selected liquid remains within the grooves 16 of the heat pipe 15.

The heat pipe 15 may comprise aluminum or copper. Aluminum is preferred due to its advantages in weight and heat conductivity. Applicants note that although FIG. 4 depicts one cross section of a heat pipe 15 any number of cross sections are available that provide the necessary capillary action.

Referring back to FIG. 2, in application, one end (proximate end) of the heat pipe 15 is in conductive contact to a heat producing structure 5 and the other end (distal end) is displaced from the heat producing structure 5. As the heat producing structure 5 heats the proximate end of the heat pipe 15 the liquid contained within the grooves of the heat pipe 15 is vaporized. The vapor travels to the distal end of the heat pipe 15 and a remaining portion of the liquid at the distal end of the heat pipe 15 simultaneously moves to the empty portion of the grooves from which the liquid was vaporized. The vapor that moves to the distal end of the heat pipe then reliquifies into the empty portion of the grooves at the heat pipe's distal end. The vapor liquefies because it is removed from the heat source and the temperature at the distal end of the heat pipe is below the liquids boiling temperature. This movement of the liquid down the groves of the heat pipe 15 may be described as “capillary action”. The vaporization of the liquid at the proximate end of the heat pipe 15 and the liquefying of the vapor at the distal end of the heat pipe 15 effectively transfers the heat produced by the devices contained within the housing 10 to the enclosure's sidewall 20.

Examples of liquids that may be used in heat pipes 15 for computer applications include: acetone, ammonia, freon 11, freon 113, and heptane. It is noted that the previous list of heat pipe 15 liquids has been included for illustration purposes and should not serve to limit the invention to those liquids specifically mentioned, as other liquids may be utilized in the heat pipe 15 depending on the particular application and possible surface treatment of the heat pipe's 15 interior surface.

Referring back to FIG. 2, it is noted that the heat pipe 15 connects the heat producing device 5 to the sidewall 20 of the electronics device enclosure. In this embodiment, the sidewall 20 contains an intake 30 and an exhaust 25. Heat produced by the heat producing device 5 is transferred to the sidewall 20 of the electronics device enclosure by the heat pipe 15. The heated surface of the sidewall 20 is then cooled by a chimney effect that is produced in the sidewall 20 of the housing 10, which draws exhaust from the air passage into the exterior atmosphere. As heated air exits the air passage through the exhaust vent 25 cooler air from the exterior atmosphere enters the air passage through intake vent 30.

The chimney effect may be enhanced by including further intake and exhaust vents within the interior surfaces of the sidewall 20 of the electronics device enclosure. Although not depicted in the supplied illustrations, interior vents are contemplated and within the scope of the present invention. It is noted that any number of vents may be supplied in order to produce the most effective draw of heated air from the air passage and most effective draw of cooler air into the air passage from the exterior atmosphere.

Referring to FIG. 5, in another embodiment of the present invention the sidewall 20′ including the air passage may comprise of a plurality of flutes. In this embodiment of the present invention, the sidewall 20′ may still contain an intake vent 30 and an exhaust vent 25 that are positioned on the outside surfaces of the sidewall 20′. The sidewall 20′ may also contain at least one intake and/or at least one exhaust on the interior surface of the sidewall 20′.

Referring now to FIG. 6, in one example of a fluted sidewall 20′, a plurality of flutes 22 may be positioned between an interior panel 23 and an exterior panel 24 of the sidewall 20′. In this embodiment, the exterior panel 24 includes an intake vent 30 and an exhaust vent 25 and the inside panel 23 is in conductive communication with at least one heat pipe 15. Each of the flutes 22 can have an upward dimension and a base dimension. In one embodiment, the upper dimension of the flute 22 may be equal to the base dimension of the flute 22. In another embodiment of the present invention, the base dimension of the flute 22 may be greater than the upper dimension of the flute 22 in order to enhance the chimney effect.

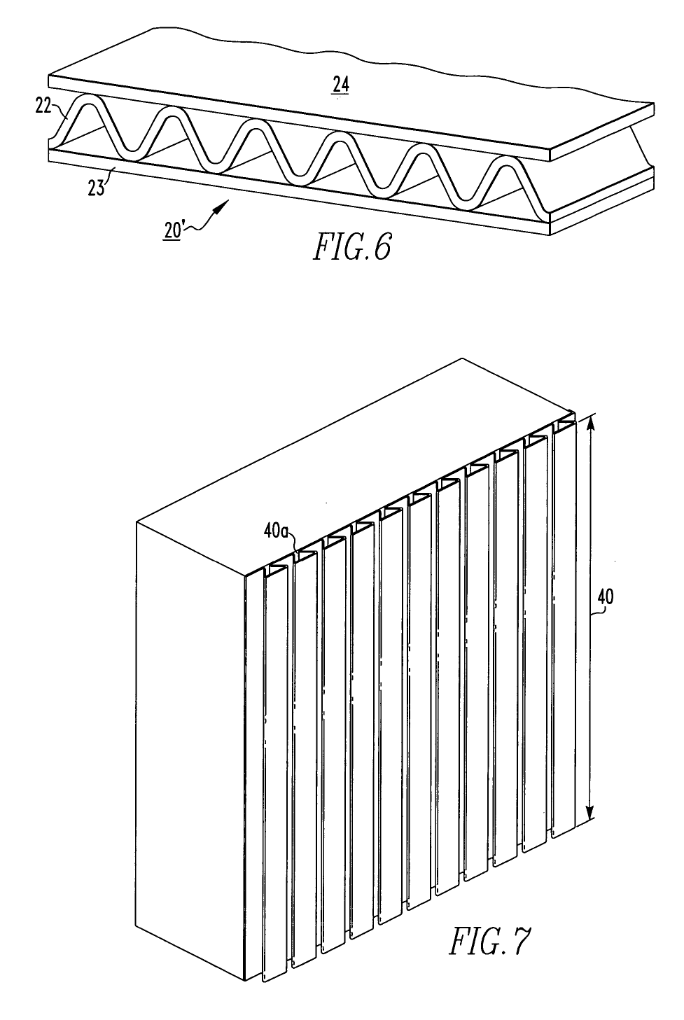

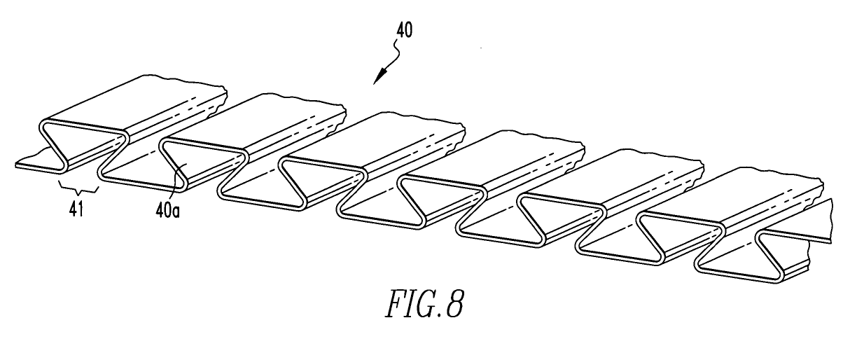

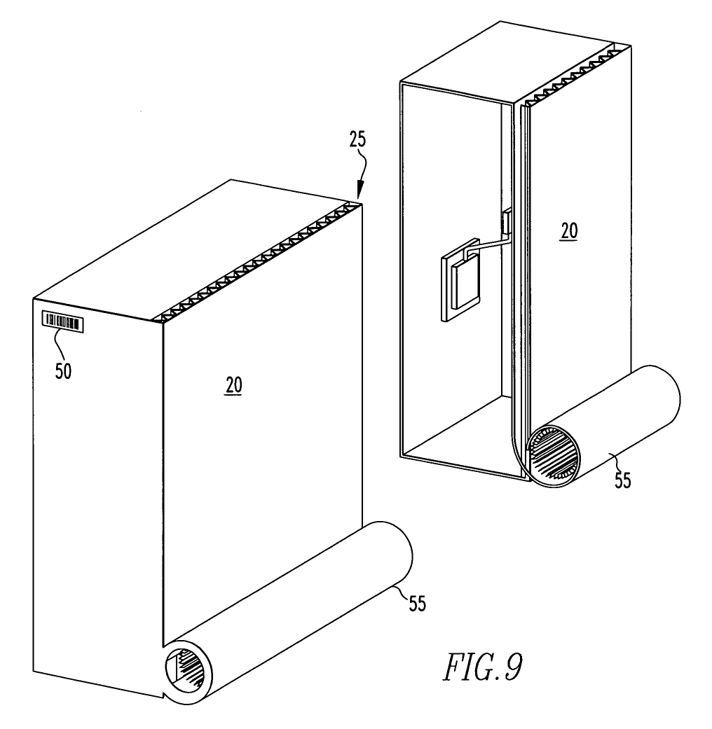

Another example of a fluted sidewall 40 is depicted in FIG. 7. In this embodiment, the fluted sidewall 40 does not contain an interior panel or an exterior panel. In this embodiment, the actual orientation and dimensions of the fluted sidewall 40 produce the chimney effect without the need of an inside panel or an outside panel. One example of a fluted sidewall cross-section that produces chimney effects without interior or exterior panels is depicted in FIG. 8. It is noted that the cross-section of each flute is designed to ensure that the heated air is directed upward while drawing cooler air into the flutes 40a. Without wishing to be limited, but in the interest of providing greater explanation, the cross section of the flutes 40a is designed to ensure that the heated air particles are insulated from cooling prior to being vented from the sidewall 40, since cooling of the particles prior to being expelled from the flutes disadvantageously effects exhaust flow.

Similar to the previously described embodiments, the upper portion of each flute 40a can have an upward dimension and a base dimension. In one embodiment, the upper dimension of the flute 40a may be equal to the base dimension of the flute 40a. In another embodiment of the present invention, the base dimension of the flute 40a may be greater than the upper dimension of the flute 40a in order to enhance the chimney effect. The chimney effect may also be advanced by increasing the flue 41 of each flute 40a.

The present invention is not limited to the cross section depicted in FIG. 8 as any fluted orientation that produces the chimney effect has been contemplated and is therefore within the scope of this disclosure.

Although the present invention provides increased cooling without the use of fans or blowers, fans and blowers may be incorporated into the above designs to further increase cooling. In one example, the fan 55 may be positioned at the intake of the sidewall 20 having the air passage, as illustrated in FIG. 9. In this embodiment, the fan 55 would push cool air from the exterior atmosphere into the air passage through the intake vent 30 to push the heated air within the air passage out the exhaust vent 25. In another example, the fan or blower may be positioned at the exhaust vent 25 of the sidewall containing the air passage, in which the fan or blower would pull hot air from the air passage into the exterior atmosphere. Pulling the hot air from the air passage would inevitably pull cool air into the air passage through the intake. Fans may be positioned at interior vents where applicable. The same principles may be applied to the embodiment illustrated in FIGS. 5 and 7. When utilized, it is preferred that the fan 55 is a low velocity fan.

In conjunction with embodiments utilizing a fan 55 to provide additional cooling it is preferred that the fan 55 is in communication with a visible signal 50 attached to the housing 30. The signal 50 being adapted to indicate when the fan 55 is inoperable. In another embodiment of the present invention, the electronic device enclosure may comprise a sensor that measures the temperature within the electronic device enclosure and powers off the heat producing electronic devices when the temperature of the enclosure increases to a point that may damage the electrical devices housed therein.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. An electronics case comprising:
a housing comprising at least one sidewall having an air passage, wherein said air passage includes an intake and an exhaust;
a heat producing structure contained by said housing; and
at least one heat pipe in conductive communication with said heat producing structure and said at least one of said sidewalls having said air passage.

2. The electronics case of claim 1 wherein said housing comprises of aluminum, copper, or steel sheets.

3. The electronics case of claim 1 wherein said intake comprises a first vent positioned on a lower outside portion of said at least one of said sidewalls having said air passage and said exhaust comprises a second vent positioned on an upper outside portion of said at least one of said sidewalls having said air passage.

4. The electronics case of claim 3 further comprising at least one interior vent positioned on a lower or upper inside portion of said at least one sidewall having said air passage.

5. The electronics case of claim 1 wherein said at least one heat pipe comprises aluminum or copper.

6. The electronics case of claim 1 further comprising a fan adapted to vent air through the air passage.

7. The electronics case of claim 5 further comprising a signal visibly positioned on said housing wherein said signal indicates operability of said fan.

8. The electronics case of claim 5 further comprising a sensor which powers down said heat producing device when said fan is inoperable.

9. The electronics case of claim 1 wherein said heat producing structure comprises a power supply, a motherboard or drive system or other modules e.g., graphics chips.

10. An electronics case comprising:
a housing comprising at least one fluted sidewall;
a heat producing structure contained by said housing; and
at least one heat pipe in conductive communication with said heat producing structure and said at least one fluted sidewall.

11. The electronics case of claim 10 wherein at least one fluted sidewall comprises a cross-section that produces a chimney effect that vents air heated by said heat producing structure from said housing.

12. The electronics case of claim 11 wherein at least one fluted sidewall further comprises an inside panel positioned on the interior surface of said at least one fluted sidewall and an outside panel positioned on said exterior surface of said at least one fluted sidewall, wherein outside panel comprises a first vent positioned on a lower portion of said outside panel and a second vent positioned on an upper portion of said outside panel.

13. The electronics case of claim 12 wherein said at least one fluted sidewall further comprises at least one interior vent positioned on said inside panel of said at least one upper or lower surface of said inside panel.

14. The electronics case of claim 10 wherein said housing comprises aluminum, copper, or steel sheets.

15. The electronics case of claim 10 wherein said at least one heat pipe comprises aluminum or copper.

16. The electronics case of claim 10 further comprising a fan adapted to vent air across said at least one fluted sidewall.

17. The electronics case of claim 16 further comprises a sensor that produces a visible signal on said housing or power down said heat producing device when said fan is inoperable.

18. The electronics case of claim 10 wherein each of said at least one fluted sidewall comprises at least one flute having a base portion with a first dimension and a top portion with a second dimension, wherein said first dimension is greater than said second dimension.

19. The electronics case of claim 1 wherein said heat producing structure comprises a power supply, a motherboard or drive system.
